(19) United States
(12) Patent Application Publication
(10) Pub. No.: US 2023/0232524 A1
(43) Pub. Date: Jul. 20, 2023

(54) LIQUID SUBMERSION COOLED ELECTRONIC DEVICE WITH CLAMSHELL ENCLOSURE

(71) Applicant: LiquidCool Solutions, Inc., Rochester, MN (US)

(72) Inventors: Lyle Rick TUFTY, Rochester, MN (US); Steve SHAFER, Rochester, MN (US)

(21) Appl. No.: 18/155,432

(22) Filed: Jan. 17, 2023

Related U.S. Application Data
(60) Provisional application No. 63/300,304, filed on Jan. 18, 2022.

(51) Int. Cl. H05K 1/02; H05K 7/20

(52) U.S. Cl. CPC H05K 1/0203; H05K 7/20236; H05K 7/20263; H05K 7/20254; H05K 7/20272; H05K 7/20409; H05K 2201/064

(57) ABSTRACT

Liquid submersion cooled electronic devices and systems are described that use one or more cooling liquids, for example one or more dielectric cooling liquids, to submersion cool individual electronic devices or an array of electronic devices. A clamshell or sandwich construction of the device housing is used to define a wet zone containing heat producing electronic components of the electronic device to be cooled by the dielectric cooling liquid, and a dry zone where input/output and power connectors are provided.

### FIELD

This technical disclosure relates to liquid submersion cooling of electronic array systems and devices.

### BACKGROUND

Liquid submersion cooled electronic systems and devices are known. Examples of liquid submersion cooled electronic systems and devices are disclosed in U.S. Pat. Nos. 7,403,392; 7,905,106; 7,911,793; 8,089,764; 8,305,759; 9,451,726; 10,271,456; 10,390,458; 10,609,839; and 11,122,704.

### SUMMARY

Liquid submersion cooled electronic devices and systems are described that use one or more cooling liquids, for example one or more dielectric cooling liquids, to submersion cool individual electronic devices or an array of electronic devices. In one embodiment, a clamshell or sandwich construction of the device housing is used to define a wet zone containing heat producing electronic components of the electronic device to be cooled by the dielectric cooling liquid, and a dry zone where input/output and power connectors are provided.

The concepts described herein can be used in any applications where electronic devices are liquid submersion cooled, including, but not limited to, liquid submerged servers, blade servers, disk arrays/storage systems, solid state memory devices, storage area networks, network attached storage, storage communication systems, routers, telecommunication infrastructure/switches, wired, optical and wireless communication devices, cell processor devices, printers, power supplies, etc.

The liquid submersion cooling devices and systems described herein can be used in any technology area that could benefit from the advantages of liquid submersion cooling. In one example, the liquid submersion cooling devices and systems can be used in blockchain computing (cryptocurrency) applications, for example in either ASIC or GPU computer mining configurations. The liquid submersion cooling devices and systems can also be used in deep learning applications, for example in multi-GPU configurations supporting maximum bandwidth and direct memory access (DMA) of high performance GPUs. The liquid submersion cooling devices and systems can also be used in artificial intelligence and high-performance computing (HPC) clusters with multiple co-processor configurations, for example multi-GPU configurations supporting DMA capabilities of GPU co-processors. Many other applications and uses of the liquid submersion cooling devices and systems described herein are possible and contemplated.

Benefits of the liquid submersion cooled electronic devices described herein include simplifying the input/output connectors and power connectors since they remain in the dry zone and do not need to be designed for exposure to liquid, reduced impact on potential signal integrity degradation due to connectors/extenders, and complete isolation of the circuit board electronics from ambient atmospheric conditions.

### DRAWINGS

FIG. 1 is a perspective view of one embodiment of a liquid submersion cooled electronic device with a clamshell enclosure.

FIG. 2 is another perspective view of the liquid submersion cooled electronic device of FIG. 1 with the top wall of the upper housing portion removed to show interior components.

FIG. 3 is an exploded view of the primary components of the liquid submersion cooled electronic device of FIGS. 1-2.

FIG. 4 is an exploded view of another embodiment of a liquid submersion cooled electronic device with a clamshell enclosure.

FIG. 5 is a perspective view of the liquid submersion cooled electronic device of FIG. 4.

FIG. 6 is another perspective view of the liquid submersion cooled electronic device of FIG. 4.

FIG. 7 is a top view of one embodiment of the liquid submersion cooled electronic device of FIGS. 4-6 with the upper housing portion removed to show interior components.

FIG. 8 is a top view of another embodiment of the liquid submersion cooled electronic device of FIGS. 4-6 with the upper housing portion removed to show interior components.

FIG. 9 is a top view of another embodiment of the liquid submersion cooled electronic device of FIGS. 4-6 with the upper housing portion removed to show interior components.

FIG. 10 is a cross-sectional side view taken along line 10-10 of FIG. 7 of the liquid submersion cooled electronic device of FIGS. 4-6.

FIG. 11 is a cross-sectional side view taken along line 11-11 of FIG. 7 of the liquid submersion cooled electronic device of FIGS. 4-6.

### DETAILED DESCRIPTION

The cooling liquid(s) described herein can be, but are not limited to, dielectric liquid(s). The cooling liquid is preferably a single phase dielectric cooling liquid. It is preferred that the single phase dielectric cooling liquid have a high enough thermal transfer capability and heat capacity to handle the amount of heat being generated by the submerged heat generating electronic components so that the cooling liquid does not change state from a liquid to a gas during the heat absorption process. Submersion cooling of a component means that enough of the cooling liquid is present so that the component is partially or fully submerged in the cooling liquid in direct intimate contact with the cooling liquid.

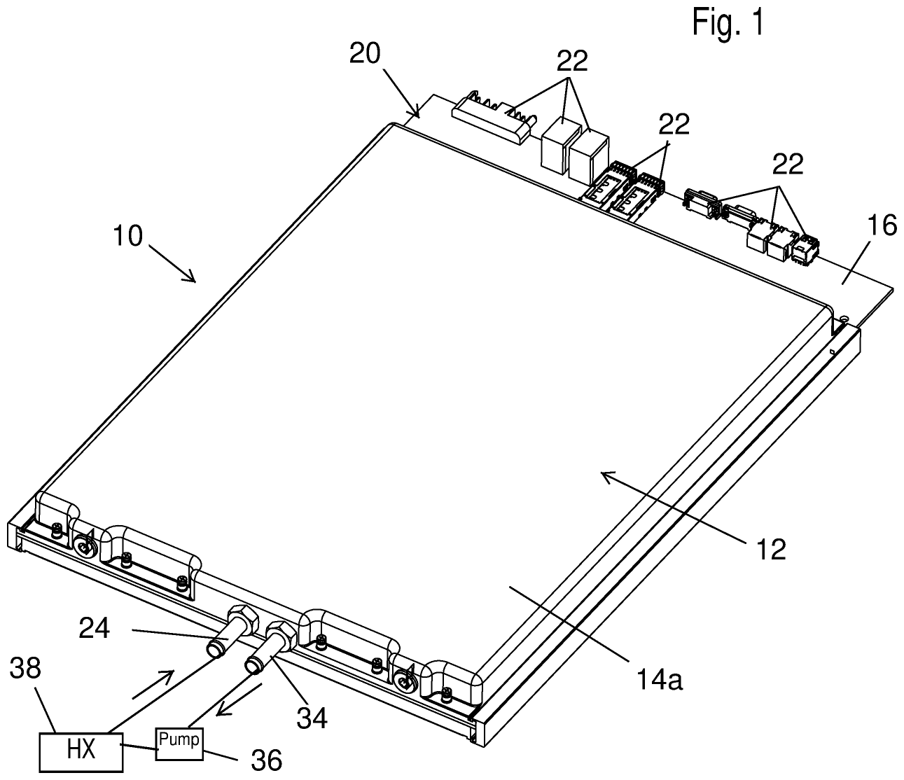

FIGS. 1-3 illustrate an example of a liquid submersion cooled electronic device 10. In this example, the device 10 uses a clamshell enclosure (also referred to as a sandwich enclosure) with a single circuit board. However, a larger number of circuit boards can be provided. In one embodiment, the device 10 can have a 1 U size although other sizes are possible.

Referring to FIGS. 1-3, the device 10 includes a sealed device housing 12 that is liquid-tight and that is formed by a first housing portion 14a and a second housing portion 14b. A circuit board 16 is at least partially disposed in the housing 12. Heat producing electronic components are mounted on a first side of the circuit board 16. The electronic components can include, but are not limited to, processors such as CPUs and/or GPUs, one or more power supplies, one or more switches, one or more data storage drives, one or more memory modules, and other electronic components.

The housing portions 14a, 14b are sealed with first and second (or upper and lower) surfaces of the circuit board 16. In particular, the electronic components are laid out on the circuit board 16 to provide a perimeter zone that is free of electronics to allow edges of the housing portions 14a, 14b to seal with the circuit board surfaces along continuous seal zones to form an interior space or wet interior space. For example, in one embodiment, sealing gaskets 18a, 18b can be provided between the edges of the housing portions 14a, 14b and the circuit board 16 to provide a liquid-tight seal. The gaskets 18a, 18b can be, but are not limited to, formed in place gaskets, o-rings nested into machined channel glands in the edges of the housing portions 14a, 14b and/or in the surfaces of the circuit board 16, or any other type(s) of seals suitable to prevent fluid leakage.

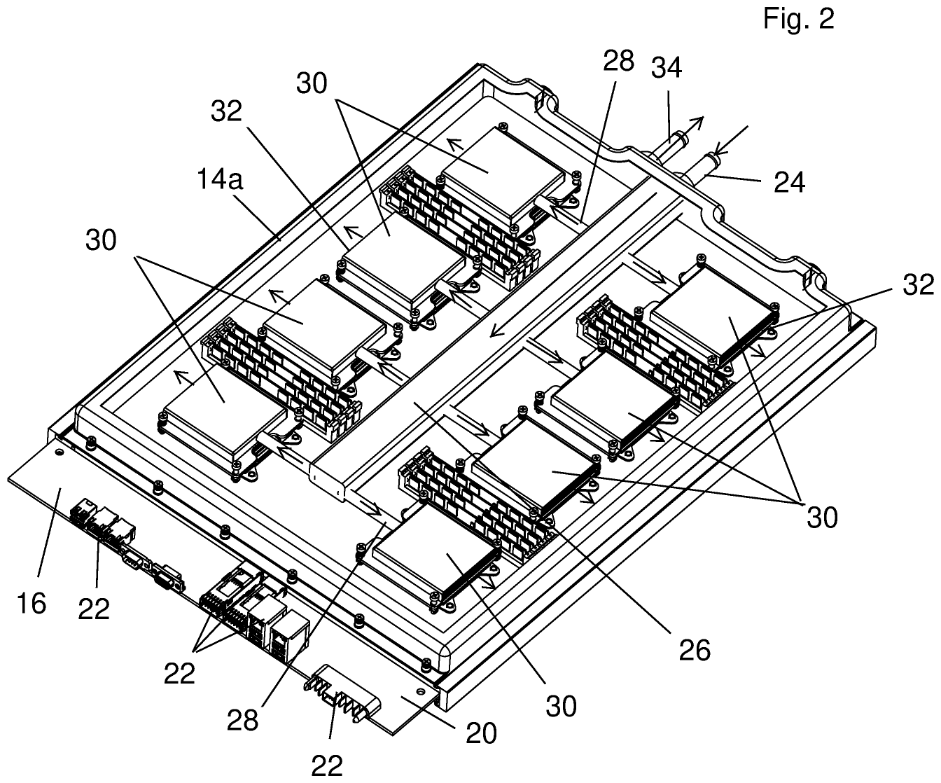

As shown in FIGS. 1 and 2, a portion 20 of the circuit board 16 is not contained within the housing 12 and forms a dry portion of the circuit board 16. Elements 22 are mounted on the dry portion 20 and are electrically connected to the heat producing electronic components disposed within the interior space. The elements 22 can be input/output connectors for data and/or for power and/or for control signals.

A cooling fluid inlet 24 is provided in the first housing portion 14a for introducing a cooling liquid, or example a dielectric cooling liquid, into the interior space of the housing 12. In the illustrated example, the cooling fluid inlet 24 is fluidly connected to an inlet manifold 26 disposed within the interior space. A plurality of feed branches 28 extend from the manifold 26 to cooling housings 30. The illustrated example depicts eight feed branches 28 and eight cooling housings 30. However, a smaller or larger number of feed branches 28 and cooling housings 30 can be used.

The cooling housings 30 are disposed around individual ones of the heat producing electronic components, such as individual CPUs or GPUs, or disposed around finned heat sinks that are attached to the individual heat producing electronic components, to direct returning flow of the cooling liquid over and around the electronic components or heat sinks. The cooling liquid is discharged from the cooling housings 30 via one or more openings 32 as depicted by the arrows in FIG. 2 into the interior space of the housing 12.

The cooling liquid discharged from the cooling housings 30 mixes with bulk cooling liquid within the interior space. The bulk cooling liquid substantially fills the entire interior space of the housing 12 and is in direct contact with the surface of the circuit board 16, and submerges the cooling housings 30 and other electronic components on the circuit board 16. Bulk cooling liquid is discharged from the housing 12 via a cooling fluid outlet 34 that is provided in the first housing portion 14a. As depicted in FIG. 1, the outlet 34 is connected to a pump 36 which pumps the cooling liquid to a heat exchanger 38 where the cooling liquid is cooled before being returned back to the inlet 24. The heat exchanger 38 can have any construction that is suitable for cooling the returning the cooling liquid prior to being returned to the housing 12. For example, the heat exchanger can be a liquid-to-liquid heat exchanger or a liquid-to-air heat exchanger.

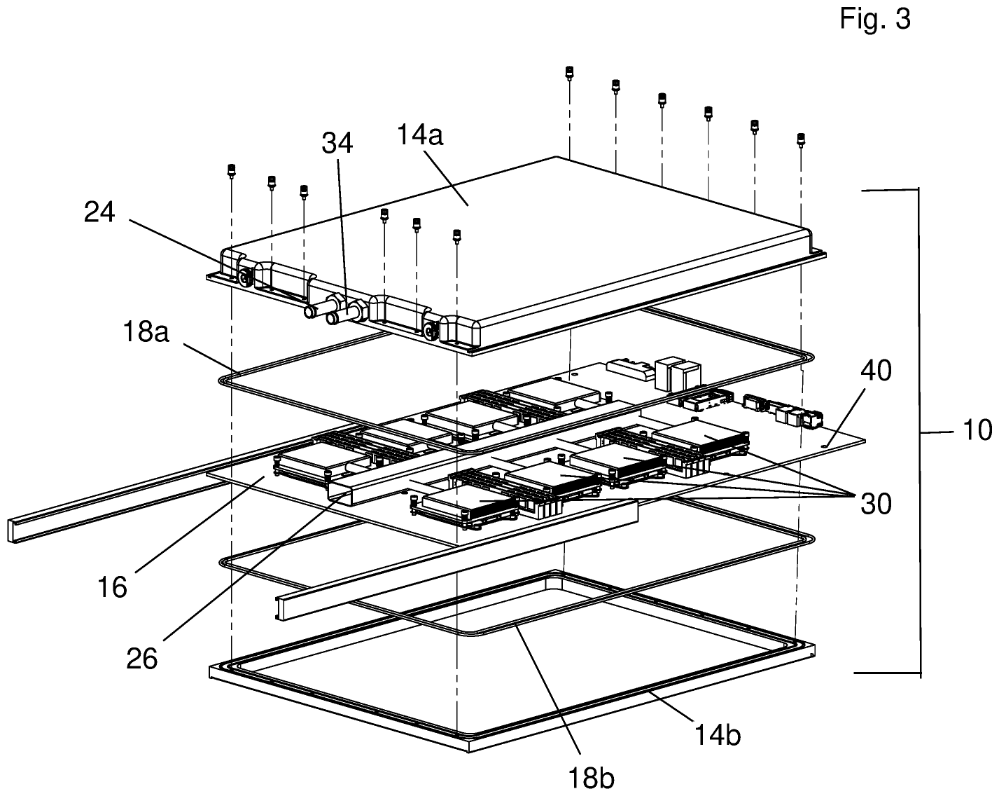

In an embodiment, one or more openings 40 (best seen in FIG. 3) can be provided in the circuit board 16 that provides fluid communication between each side of the circuit board 16 so that the cooling liquid is disposed on each side of the circuit board 16 in respective wet interior spaces on each side of the circuit board 16. In another embodiment, heat producing electronic components (not shown) together with cooling housings (not shown but similar to the cooling housings 30) can be provided on each side of the circuit board 16, and cooling fluid can be provided to the cooling housings in a manner similar to the cooling housings 30.

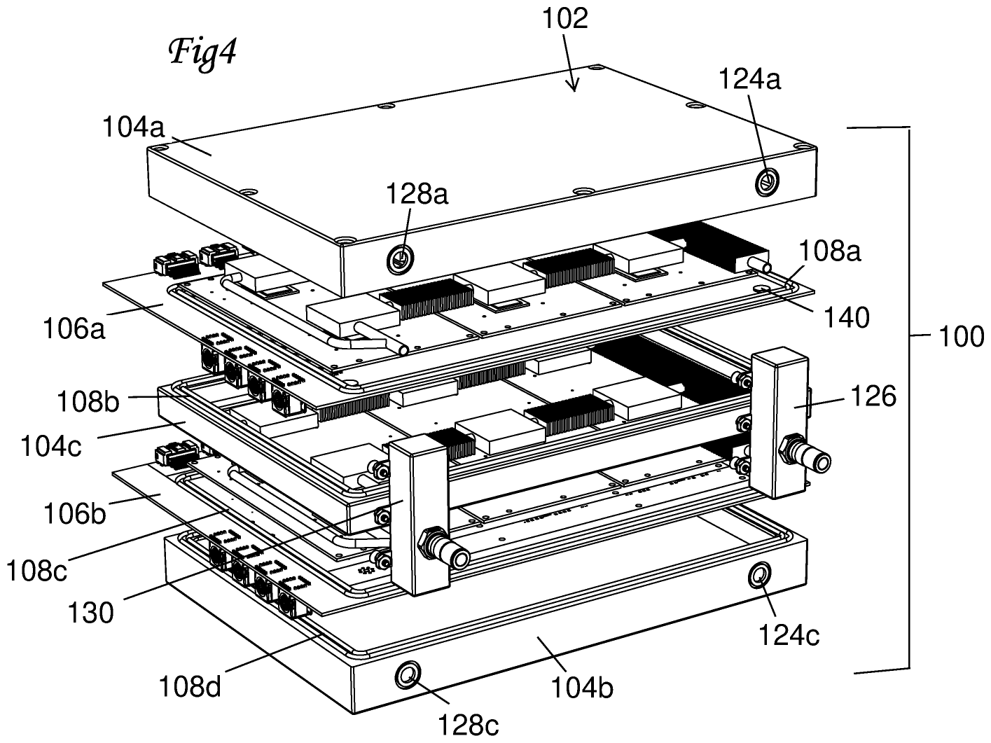

FIGS. 4-11 illustrate another example of a liquid submersion cooled electronic device 100. In this example, the device 100 uses a clamshell enclosure (also referred to as a sandwich enclosure) with a plurality of circuit boards, for example two circuit boards. However, the device 100 can be provided with a single circuit board or more than two circuit boards.

Referring to FIGS. 4-6, the device 100 includes a sealed device housing 102 that is liquid-tight and that is formed by a number of housing portions including a first housing portion 104a, a second housing portion 104b, and a third or intermediate housing portion 104c. A plurality of circuit boards, in this example two circuit boards 106a, 106b, are at least partially disposed in the housing 102. The specific construction of each of the circuit boards 106a, 106b may differ from one another. However, the circuit boards 106a, 106b ae similar in that they each have heat producing electronic components that are mounted on a first and/or second side of the circuit board 106a, 106b. The electronic components can include, but are not limited to, processors such as CPUs and/or GPUs, one or more power supplies, one or more switches, one or more data storage drives, one or more memory modules, and other electronic components.

The housing portions 104a, 104c are sealed with first and second (or upper and lower) surfaces of the circuit board 106a respectively, while the housing portions 104c, 104b are sealed with first and second (or upper and lower) surfaces of the circuit board 106b respectively. In particular, the electronic components are laid out on the circuit boards 106a, 106b to provide perimeter zones that are free of electronics to allow edges of the housing portions 104a, 104c and 104c, 104b to seal with the respective circuit board surfaces along continuous seal zones to form interior spaces or wet interior spaces. For example, in one embodiment, sealing gaskets 108a, 108b can be provided between the edges of the housing portions 104a, 104c and the circuit board 106a to provide a liquid-tight seal. Similarly, sealing gaskets 108c, 108d can be provided between the edges of the housing portions 104c, 104d and the circuit board 106b to provide a liquid-tight seal. The gaskets 108a, 108b, 108c, 108d can be, but are not limited to, formed in place gaskets, o-rings nested into machined channel glands in the edges of the housing portions 104a, 104b, 104c and/or in the surfaces of the circuit boards 106a, 106b, or any other type(s) of seals suitable to prevent fluid leakage.

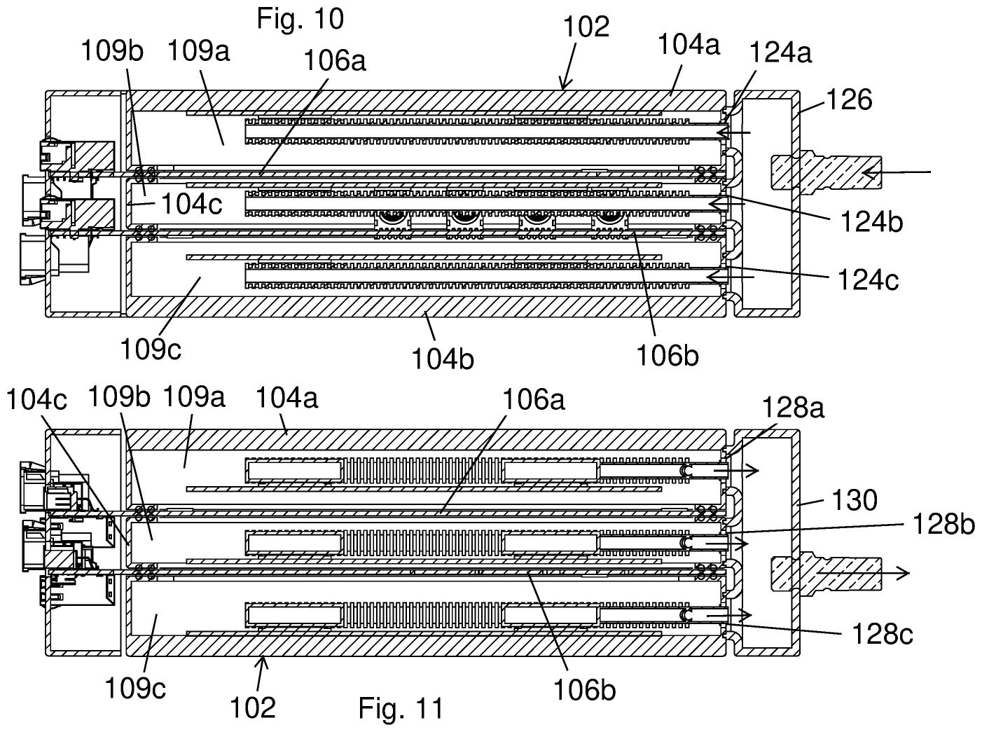

Referring to FIGS. 10-11, when assembled with the circuit boards 106a, 106b, the housing 102 includes a first interior space/wet interior space 109a defined by the housing portion 104a and the upper surface of the circuit board 106a; a second interior space/wet interior space 109b defined by the housing portion 104c, the lower surface of the circuit board 106a and the upper surface of the circuit board 106b; and a third interior space/wet interior space 109c defined by the housing portion 104b and the lower surface of the circuit board 106b. In an embodiment, the spaces 109a, 109b, 109c may be fluidly separated from each other. In another embodiment, the spaces 109a, 109b, 109c may be in fluid communication with each other, for example via one or more openings 140 in the circuit boards 106a, 106b as best seen in FIGS. 4 and 7-9. The openings 140 equalize the fluid pressure in the spaces 109a, 109b, 109c.

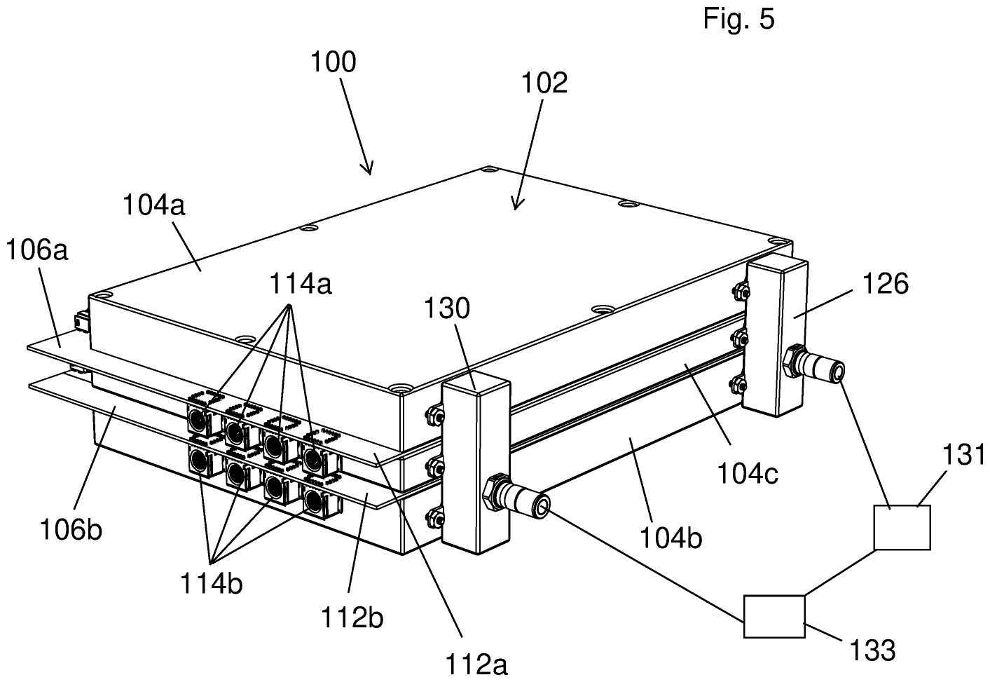

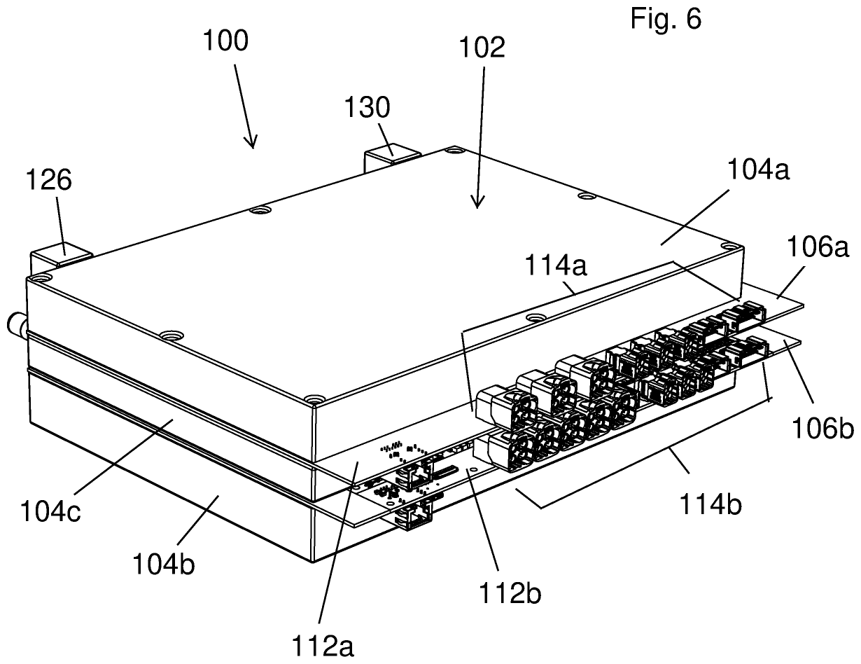

Referring to FIGS. 5 and 6, portions 112a, 112b of each of the circuit boards 106a, 106b are not contained within the housing 102 and form dry portions of the circuit board 106a, 106b. FIGS. 5-6 illustrate each of the circuit boards 106a, 106b as having two dry portions 112a, 112b that extend from different sides of the housing 102. Elements 114a, 114b are mounted on the dry portions 112a, 112b and are electrically connected to the heat producing electronic components disposed within the interior spaces 109a, 109b, 109c. The elements 114a, 114b can be input/output connectors for data and/or for power and/or for control signals.

Referring to FIGS. 4 and 10-11, cooling fluid inlets 124a, 124b, 124c are provided in the housing portions 104a, 104b, 104c for introducing a cooling liquid into the respective interior spaces 109a, 109b, 109c of the housing 102. In the illustrated example, an inlet manifold 126 is fluidly connected to each of the cooling fluid inlets 124a, 124b, 124c for feeding cooling liquid into the inlets 124a, 124b, 124c and into the interior spaces 109a, 109b, 109c. In addition, cooling fluid outlets 128a, 128b, 128c are provided in the housing portions 104a, 104b, 104c for cooling liquid to exit from the respective interior spaces 109a, 109b, 109c of the housing 102. In the illustrated example, an outlet manifold 130 is fluidly connected to each of the cooling fluid outlets 128a, 128b, 128c to allow cooling liquid to exit the interior spaces 109a, 109b, 109c through the outlets 128a, 128b, 128c and into the outlet manifold 130. As seen in FIG. 5, the inlet manifold 126 is fluidly connected to and receives returning cooled liquid from a heat exchanger 131, while the outlet manifold 130 is fluidly connected to a pump 133 which pumps cooling liquid from the housing 102 to the heat exchanger and then back to the housing 102 after being cooled. The heat exchanger 131 can have any construction that is suitable for cooling the returning the cooling liquid prior to being returned to the housing 102. For example, the heat exchanger 131 can be a liquid-to-liquid heat exchanger or a liquid-to-air heat exchanger.

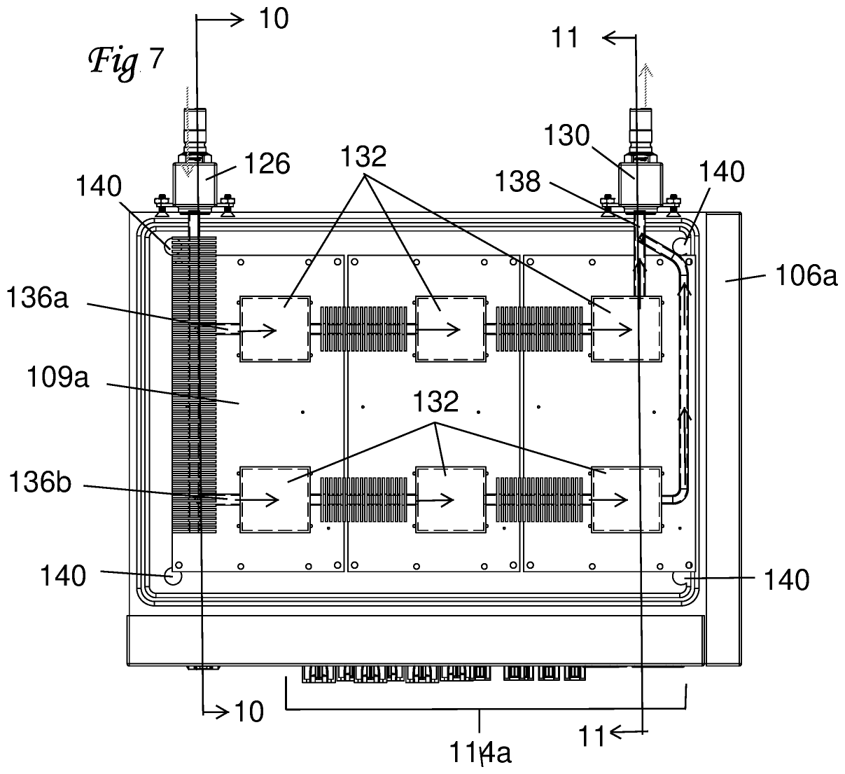

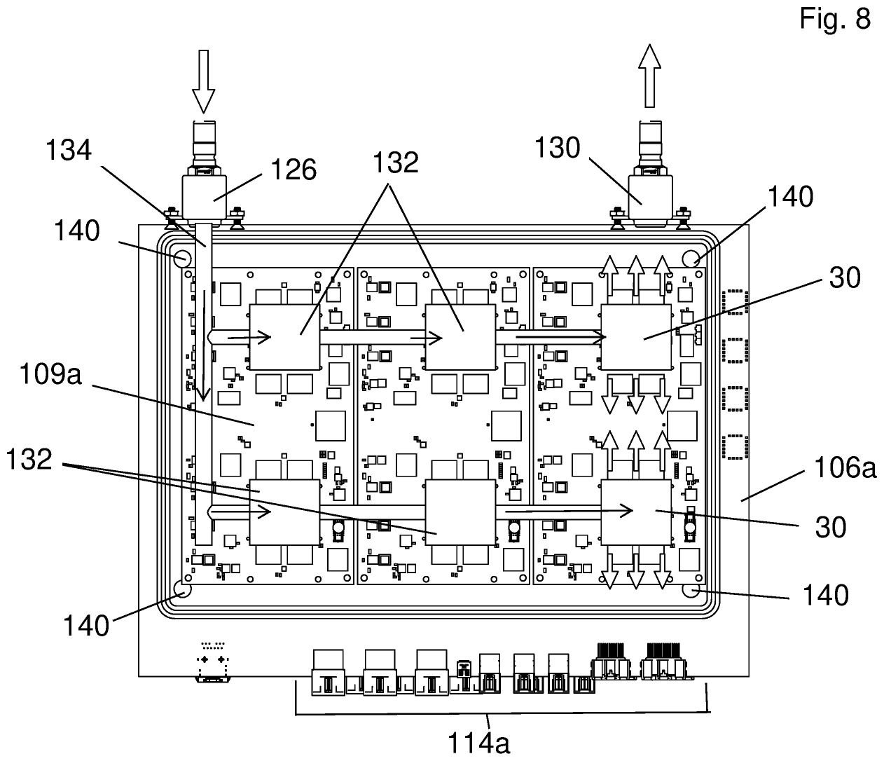

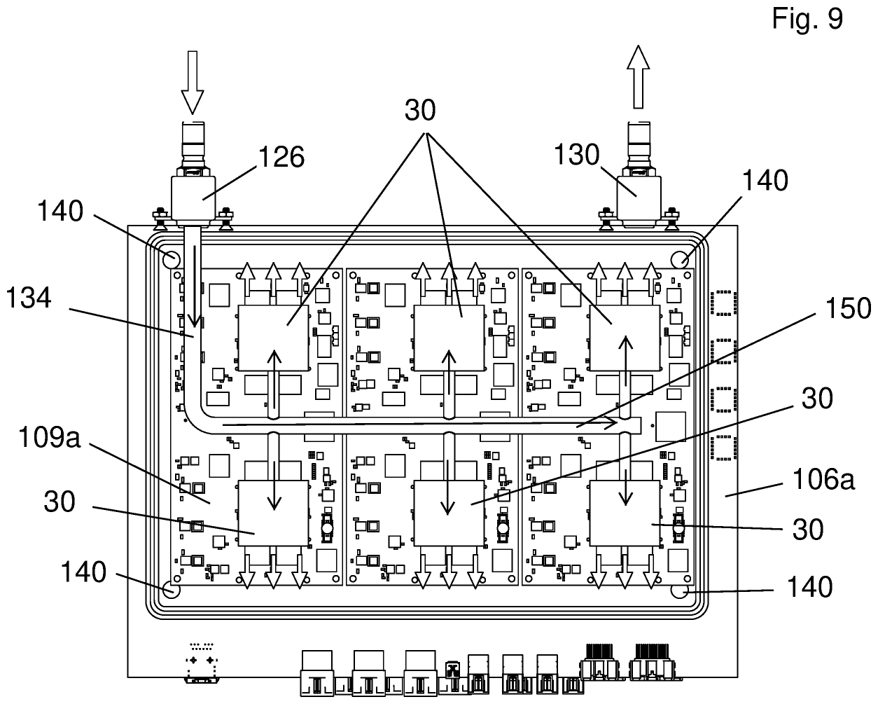

FIGS. 7-9 illustrate different embodiments of implementing liquid submersion cooling in the housing 102. FIG. 7 depicts a version that uses cold plate cooling with a first cooling liquid which is circulated outside the housing 102, together with a non-circulating, bulk cooling liquid in the interior spaces 109a, 109b, 109c. FIG. 8 depicts a version that uses serial flow cooling using a cooling liquid that ultimately mixes with bulk cooling liquid in the interior spaces 109a, 109b, 109c, with the bulk cooling liquid circulated outside the housing 102. FIG. 9 depicts a version that uses parallel flow cooling using a cooling liquid that mixes with bulk cooling liquid in the interior spaces 109a, 109b, 109c, with the bulk cooling liquid circulated outside the housing 102.

Referring first to FIG. 7, a top view of the interior space 109a of the housing 102 is illustrated. The other interior spaces 109b, 109c and the heat producing electronic components therein can have a similar construction. Cooling housings in the form of cold plates 132 are provided in heat exchanging relationship with the heat producing electronic components to be cooled. The cold plates 132 can be in direct contact with the heat producing electronic components, or in direct contact with finned heat exchangers that are in contact with the heat producing electronic components. An inlet conduit 134 extends from the inlet manifold 126 through the cooling fluid inlet and into the interior space 109a. The inlet conduit 134 includes a first branch conduit 136a and a second branch conduit 136b. The branch conduits 136a, 136b feed incoming cooling liquid into the first set of cold plates 132 in the cold plate array, with the cooling liquid then flowing from the first set of cold plates 132 into the second or middle set of cold plates 132, and then flowing from the second cold plates 132 into the last set of cold plates 132. The cooling liquid then flows from the last set of cold plates into an outlet conduit 138 that is fluidly connected to the outlet manifold 130 via the cooling fluid outlets.

At the same time, a non-circulating (i.e. not circulated outside the housing 102), bulk cooling liquid is disposed in the interior space 109a. The bulk cooling liquid submerges the heat producing electronic components and partially or fully submerges the cold plates 132. The bulk cooling liquid may fill substantially the entire volume of the interior space 109a or fill only a portion of the volume of the interior space 109a as long as the heat producing electronic components and the cold plates 132 are submerged. In an embodiment, heat exchange fins 142 can be provided on an exterior surface of the inlet conduit 134 and/or on exterior surfaces of conduits connecting the cold plates 132. The fins 142 are partially or fully submerged in the bulk cooling liquid.

In the embodiment in FIG. 7, the cooling liquid directed into the cold plates 132 and the bulk cooling liquid in the interior spaces of the housing 102 do not mix with one another. In an embodiment, the cooling liquids may be the same cooling liquids as one another (i.e. identical liquids having the same compositions). In another embodiment, the cooling liquids may be of the same type but have different compositions from each other. For example, both cooling liquids can be single-phase dielectric cooling liquids (i.e. same type), but the cooling liquid of the cold plates 132 can be a first dielectric cooling liquid while the bulk cooling liquid can be a second dielectric cooling liquid different from the first. In another embodiment, the cooling liquids may be of different types from each another and have different compositions from each other. For example, the cooling liquid of the cold plates 132 can be a first cooling liquid (for example water or glycol) while the bulk cooling liquid can be a dielectric cooling liquid.

In a modification of FIG. 7, instead of serial flow of the coolant through the cold plates 132 as depicted, a parallel flow arrangement can be used. In this arrangement, a manifold (not shown, but similar to the manifold 26 described in FIG. 2 or similar to the manifold described below in FIG. 9) can feed incoming coolant into each one of the cold plates 132, with outlet passages then extending from each one of the cold plates 132 to the outlet conduit 138 to direct the returning coolant to the outlet conduit 138.

Referring to FIG. 8, a top view of the interior space 109a of the housing 102 is illustrated. The other interior spaces 109b, 109c and the heat producing electronic components therein can have a similar construction. In FIG. 8, elements that are similar or identical to elements in FIG. 7 are referenced using the same reference numerals. Cooling housings are provided in heat exchanging relationship with the heat producing electronic components to be cooled. In the illustrated example, the cooling housings include a number of the cold plates 132 that are in direct contact with the heat producing electronic components, or in direct contact with finned heat exchangers that are in contact with the heat producing electronic components. The cold plates 132 are isolated from the bulk cooling liquid in the interior space 109a and do not discharge directly into the bulk cooling liquid. The other cooling housings are like the cooling housings 30 in FIGS. 1-3 and receive cooling liquid from the cold plates 132. The cooling liquid in the cooling housings 30 is then discharged from the cooling housings 30 directly into the bulk cooling liquid in the interior space 109a as indicated by the arrows in FIG. 8.

The inlet conduit 134 extends from the inlet manifold 126 through the cooling fluid inlet and into the interior space 109a. The inlet conduit 134 includes the first branch conduit and the second branch conduit. The branch conduits feed incoming cooling liquid into the first set of cold plates 132 in the cold plate array, with the cooling liquid then flowing from the first set of cold plates 132 into the second or middle set of cold plates 132. The cooling liquid then flows into the cooling housings 30, and is then discharged from the cooling housings 30 into the bulk cooling liquid in the interior space 109a.

In the example in FIG. 8, the bulk cooling liquid is disposed in the interior space 109a. The bulk cooling liquid submerges the heat producing electronic components and partially or fully submerges the cold plates 132 and the cooling housings 30. The bulk cooling liquid may fill substantially the entire volume of the interior space 109a or fill only a portion of the volume of the interior space 109a as long as the heat producing electronic components and the cold plates 132 and the cooling housings 30 are submerged. In an embodiment, heat exchange fins, like the fins 142 in FIG. 7, can be provided on an exterior surface of the inlet conduit 134 and/or on the passages connecting the cold plates 132 and/or on the passage connecting the cold plates 132 to the cooling housings 30.

In the embodiment in FIG. 8, the cooling liquid directed into the cold plates 132 and the other cooling housings 30 ultimately is discharged into and mixes with the bulk cooling liquid. Accordingly, it is preferred that the cooling liquids are the same cooling liquids as one another (i.e. identical liquids such as single-phase dielectric cooling liquid having the same compositions).

Referring to FIG. 9, a top view of the interior space 109a of the housing 102 is illustrated. The other interior spaces 109b, 109c and the heat producing electronic components therein can have a similar construction. In FIG. 9, elements that are similar or identical to elements in FIGS. 7 and 8 are referenced using the same reference numerals. Cooling housings are provided in heat exchanging relationship with the heat producing electronic components to be cooled. In the illustrated example, the cooling housings are like the cooling housings 30 in FIGS. 1-3 which discharge the cooling liquid therefrom directly into the bulk cooling liquid in the interior space 109a as indicated by the arrows. The cooling housings 30 are fed with cooling liquid via a central manifold 150 that is fluidly connected to the inlet conduit 134.

In the example in FIG. 9, the bulk cooling liquid is disposed in the interior space 109a. The bulk cooling liquid submerges the heat producing electronic components and partially or fully submerges the cooling housings 30. The bulk cooling liquid may fill substantially the entire volume of the interior space 109a or fill only a portion of the volume of the interior space 109a as long as the heat producing electronic components and the cooling housings 30 are submerged. In an embodiment, heat exchange fins, like the fins 142 in FIG. 7, can be provided on an exterior surface of the inlet conduit 134 and/or on the manifold 150 and/or on the passages connecting the manifold 150 to cooling housings 30.

In the embodiment in FIG. 9, the cooling liquid directed into the cooling housings 30 is ultimately is discharged into and mixes with the bulk cooling liquid. Accordingly, it is preferred that the cooling liquids are the same cooling liquids as one another (i.e. identical liquids such a single-phase dielectric liquids having the same compositions).

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A liquid submersion cooled electronic device, comprising:
a circuit board having a first side and a second side, first heat producing electronic components mounted on the first side of the circuit board, and an input/output connector mounted on the circuit board and electrically connected to the first heat producing electronic components;
a first housing portion that is in direct sealing engagement with the first side of the circuit board via a first seal that surrounds the first heat producing electronic components to define a first wet interior space, and the input/output connector is disposed outside the first wet interior space;
first cooling housings associated with corresponding ones of the first heat producing electronic components;
a cooling fluid inlet in the first housing portion that is in fluid communication with each one of the first cooling housings and directing single-phase cooling liquid into each one of the first cooling housings; and
a single-phase bulk dielectric cooling liquid in the first wet interior space in direct contact with the first side of the circuit board and submerging the first cooling housings.

2. The liquid submersion cooled electronic device of claim 1, further comprising:
second heat producing electronic components mounted on the second side of the circuit board;
a second housing portion that is in direct sealing engagement with the second side of the circuit board via a second seal that surrounds the second heat producing electronic components to define a second wet interior space, and an input/output connector is electrically connected to the second heat producing electronic components and is disposed outside the second wet interior space;
second cooling housings associated with corresponding ones of the second heat producing electronic components;
a cooling fluid inlet in the second housing portion that is in fluid communication with each one of the second cooling housings and directing single-phase cooling liquid into each one of the second cooling housings; and
a single-phase bulk dielectric cooling liquid in the second wet interior space in direct contact with the second side of the circuit board and submerging the second cooling housings.

3. The liquid submersion cooled electronic device of claim 2, further comprising an opening in the circuit board that provides fluid communication between the first wet interior space and the second wet interior space.

4. The liquid submersion cooled electronic device of claim 1, wherein the first cooling housings include fluid outlets through which the single-phase cooling liquid therein is discharged directly into the single-phase bulk dielectric cooling liquid in the first wet interior space.

5. The liquid submersion cooled electronic device of claim 1, wherein the first housing portion includes a cooling fluid outlet that is in fluid communication with each one of the first cooling housings and receiving the single-phase cooling liquid therefrom, wherein the single-phase cooling liquid is isolated from and does not mix with the single-phase bulk dielectric cooling liquid in the first wet interior space.

6. A liquid submersion cooled electronic device, comprising:
a sealed device housing that is liquid-tight and that defines a first interior space;
a first circuit board at least partially disposed in the sealed device housing and defining at least a portion of the first interior space, heat producing electronic components mounted on the first circuit board within the first interior space;
first cold plates in the first interior space and in heat exchanging relationship with the heat producing electronic components;
a first cooling liquid inlet in the sealed device housing that is in fluid communication with each one of the first cold plates and directing single-phase cooling liquid into each one of the first cold plates;
a first cooling liquid outlet in the sealed device housing that is in fluid communication with each one of the first cold plates and receiving the single-phase cooling liquid from each one of the first cold plates; and
a single-phase bulk dielectric cooling liquid in the first interior space and submerging the first cold plates, wherein the single-phase bulk dielectric cooling liquid is isolated from and does not mix with the single-phase cooling liquid that flows through the first cold plates.

7. The liquid submersion cooled electronic device of claim 6, wherein the single-phase bulk dielectric cooling liquid is not circulated outside the sealed device housing.

8. The liquid submersion cooled electronic device of claim 6, further comprising an inlet conduit extending from the first cooling liquid inlet and into the interior space, the inlet conduit is submerged in the single-phase bulk dielectric cooling liquid, and further comprising heat exchange fins on an exterior surface of the inlet conduit.

9. The liquid submersion cooled electronic device of claim 6, wherein the sealed device housing defines a second interior space that is spaced from the first interior space;
a second circuit board at least partially disposed in the sealed device housing and spaced from the first circuit board, the second circuit board defining at least a portion of the second interior space, heat producing electronic components mounted on the second circuit board within the second interior space;
second cold plates in the second interior space and in heat exchanging relationship with the heat producing electronic components on the second circuit board;
a second cooling liquid inlet in the sealed device housing that is in fluid communication with each one of the second cold plates and directing single-phase cooling liquid into each one of the second cold plates;
a second cooling liquid outlet in the sealed device housing that is in fluid communication with each one of the second cold plates and receiving the single-phase cooling liquid from each one of the second cold plates; and
a single-phase bulk dielectric cooling liquid in the second interior space and submerging the second cold plates, wherein the single-phase bulk dielectric cooling liquid in the second interior space is isolated from and does not mix with the single-phase cooling liquid flowing through the second cold plates.

10. The liquid submersion cooled electronic device of claim 9, further comprising an inlet manifold mounted on the sealed device housing on an exterior thereof; the first cooling liquid inlet and the second cooling liquid inlet are formed in the inlet manifold.

11. The liquid submersion cooled electronic device of claim 9, further comprising an outlet manifold mounted on the sealed device housing on an exterior thereof; the first cooling liquid outlet and the second cooling liquid outlet are formed in the outlet manifold.

12. A liquid submersion cooled electronic device, comprising:
a sealed device housing that is liquid-tight;
a first circuit board at least partially disposed in the sealed device housing, the first circuit board includes a first side and a second side, and heat producing electronic components mounted on the first circuit board;
the first side facing and at least partially defining a first interior space of the sealed device housing;
the second side facing and at least partially defining a second interior space of the sealed device housing;
a single-phase bulk dielectric cooling liquid in the first interior space and in the second interior space and in direct contact with the first side and the second side of the circuit board;
an inlet manifold mounted on the sealed device housing on an exterior thereof;
a first cooling liquid inlet formed in the sealed device housing and fluidly connected to the inlet manifold, the first cooling liquid inlet directing single-phase cooling liquid from the inlet manifold into the first interior space; and
a second cooling liquid inlet formed in the sealed device housing and fluidly connected to the inlet manifold, the second cooling liquid inlet directing single-phase cooling liquid from the inlet manifold into the second interior space.

13. The liquid submersion cooled electronic device of claim 12, further comprising an outlet manifold mounted on the sealed device housing on the exterior thereof;
a first cooling liquid outlet formed in the sealed device housing and fluidly connected to the outlet manifold, the first cooling liquid outlet directing single-phase cooling liquid from the first interior space and into the outlet manifold; and
a second cooling liquid outlet formed in the sealed device housing and fluidly connected to the outlet manifold, the second cooling liquid outlet directing single-phase cooling liquid from the first interior space and into the outlet manifold.

14. The liquid submersion cooled electronic device of claim 12, further comprising an opening formed in the first circuit board that allows fluid communication between the first interior space and the second interior space.

15. The liquid submersion cooled electronic device of claim 12, further comprising:
a second circuit board at least partially disposed in the sealed device housing and spaced from the first circuit board, the second circuit board is parallel to the first circuit board, the second circuit board includes a first side and a second side, and heat producing electronic components mounted on the second circuit board;
the first side of the second circuit board faces and at least partially defines the second interior space;
the second side of the second circuit board faces and at least partially defines a third interior space of the sealed device housing;
the single-phase bulk dielectric cooling liquid is in the third interior space and in the second interior space and in direct contact with the first side and the second side of the second circuit board;
a third cooling liquid inlet formed in the sealed device housing and fluidly connected to the inlet manifold, the third cooling liquid inlet directing single-phase cooling liquid from the inlet manifold into the third interior space.

16. The liquid submersion cooled electronic device of claim 15, further comprising an opening formed in the second circuit board that allows fluid communication between the second interior space and the third interior space.

17. The liquid submersion cooled electronic device of claim 13, further comprising a plurality of cold plates in heat exchange relationship with the heat producing electronic components mounted on the first circuit board; the first cooling liquid inlet and the first cooling liquid outlet are fluidly connected to the cold plates; wherein the single-phase cooling liquid is isolated from and does not mix with the single-phase bulk dielectric cooling liquid.

18. The liquid submersion cooled electronic device of claim 13, further comprising a plurality of cooling housings associated with corresponding ones of the heat producing electronic components on the first circuit board; the first cooling liquid inlet is fluidly connected to the cooling housings; and the cooling housings include fluid outlets through which the single-phase cooling liquid therein is discharged directly into the single-phase bulk dielectric cooling liquid.
